(19) United States
(12) Patent Application Publication
(10) Pub. No.: US 2012/0056218 A1
(43) Pub. Date: Mar. 8, 2012

(54) LEAD FRAME PACKAGE WITH MULTIPLE BENDS

(76) Inventors: Norfidathul Aizar Abdul Karim, Simpang Ampat (MY); Chiau Jin Lee, Penang (MY); Keat Chuan Ng, Penang (MY)

(21) Appl. No.: 12/877,796

(22) Filed: Sep. 8, 2010

(51) Int. Cl. H01L 33/62; H01L 33/08; H01L 33/60

(52) U.S. Cl. 257/91; 257/99; 257/98; 257/E33.066; 257/E33.067

(57) ABSTRACT

A lead frame package with multiple bends suitable for a light-emitting device, as well as a non-optical device is disclosed. A light-emitting device incorporating the lead frame package with multiple bends may comprise a light source die, a body and a plurality of leads. A non-optical device incorporating the lead frame package may comprise a die, a body and a plurality of leads. Each of the leads has at least first, second, and third bends defining each of the leads into at least first, second, third and fourth sections. At least the second section, the third section and the second bends of each lead are encapsulated by an encapsulating material forming the body.

### BACKGROUND

Light emitting diodes (referred to hereinafter as LEDs) represent one of the most popular light-emitting devices today. Due to its small form factor, an LED finds new application in electronic infotainment display systems, which may commonly be found in stadiums, discotheques, electronic traffic sign displays and infotainment boards along streets. Most of these electronic infotainment display systems are placed outdoors and thus require specifications, such as wider operating temperature, resistance to moisture, and longer lifetime. The electronic infotainment display systems used for displaying traffic information outdoors may be required to function in inclement conditions, such as rain, snow, or hot weather—as high as 60 degree Celsius in deserts.

Unlike conventional electrical appliances, electronic infotainment system may not have a housing to protect the electronic devices in the system. This is because a housing, even a transparent one, may affect the visibility of the infotainment system due to the reflection of light from the surface. In addition, an electronic infotainment display system may be so large that making a large enough protective housing may not be a cost effective or otherwise viable solution.

Therefore, for many such outdoor electronic system applications, silicone potting is commonly utilized to protect the electronic components from the elements. Silicone potting is a process in which all the electronics devices on the display are encapsulated with a potting agent. The potting agent may be made from silicone to prevent moisture from seeping into the electronic parts.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements.

FIG. 1A illustrates an isometric view of a light-emitting device with a lead frame package;

FIG. 1B illustrates a cross-sectional view of the light-emitting device taken along line 2-2 shown in FIG. 1A;

FIG. 2 illustrates a cross-sectional view of a light-emitting device having a lead frame package with multiple bends;

FIG. 3 illustrates a cross-sectional view of a light-emitting device having a lead frame package with multiple bends;

FIG. 4 illustrates a cross-sectional view of a light-emitting device having a lead frame package with outwardly bent leads;

FIG. 5 illustrates a through hole light-emitting device having a lead frame package with multiple bends;

FIG. 6A illustrates a lead frame of a light-emitting device during fabrication process;

FIG. 6B illustrates the lead frame of the light-emitting device after first bending process;

FIG. 6C illustrates the semi-finished light-emitting device after molding process;

FIG. 6D illustrates the semi-finished light-emitting device after second bending process;

FIG. 6E illustrates the semi-finished light-emitting device after die attach process;

FIG. 6F illustrates the finished light-emitting device after removal of the lead frame;

FIG. 7A illustrates a non-optical device having a lead frame package with multiple bends;

FIG. 7B illustrates a cross-sectional view of the non-optical device; and,

FIG. 8 illustrates a cross-sectional view of an electronic infotainment display system.

### DETAILED DESCRIPTION

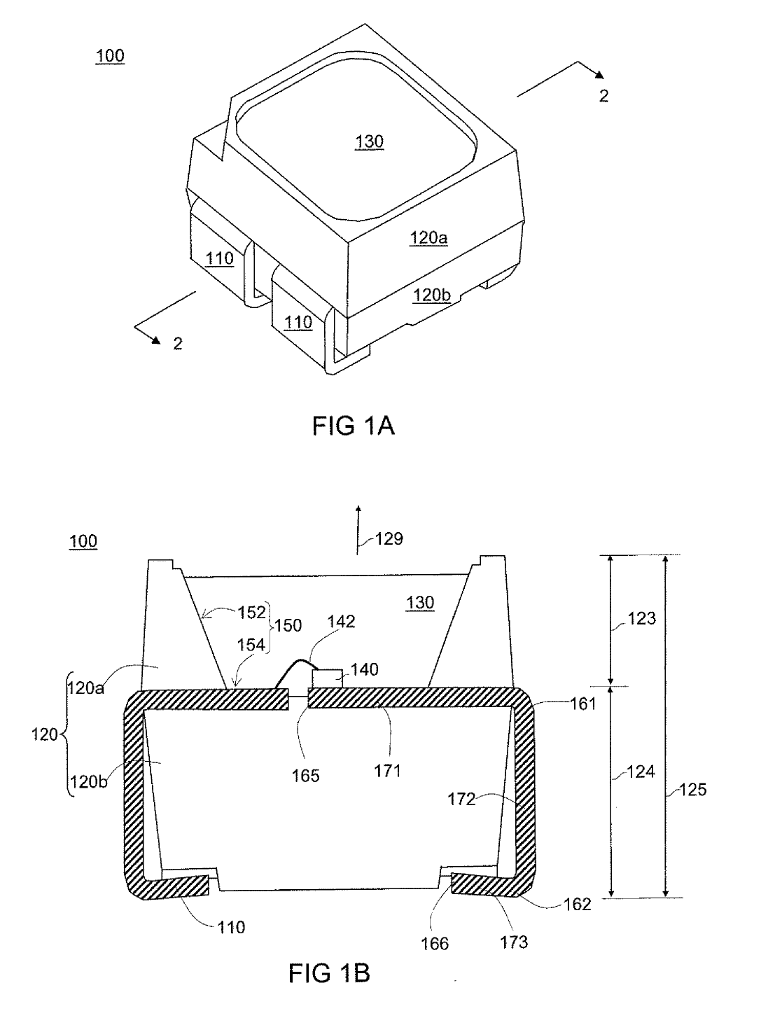

FIG. 1A illustrates an embodiment showing an isometric view of a light-emitting device 100. FIG. 1B illustrates a cross-sectional view of the light-emitting device 100 taken along section line 2-2 of FIG. 1A. The light-emitting device 100 shown in FIG. 1A-1B may be a plastic lead chip carrier type, more commonly known as a PLCC. The embodiment shown in FIG. 1A has 4 leads 110, but the light-emitting device 100 may have any number of leads 110.

Referring to FIG. 1A-1B, the light-emitting device 100 comprises a plurality of leads 110, a light source die 140 and a body 120 made from an opaque encapsulating material such as plastic. The light source die 140 may be a light-emitting device die (referred to hereinafter as an LED). The body 120 may further comprise a top portion 120a and a bottom portion 120b. The body 120 may be formed using a top mold and a bottom mold. The bottom mold may be used to form the bottom portion 120b and the top mold may be used to form the top portion 120a.

The light source die 140 may be attached to one of the leads 110. The leads 110 not receiving the light source die 140 may accommodate wire bonds 142. The leads 110 provide electrical connection to external circuits (now shown). Each of the leads 110 may have two bends 161-162 defining each lead 110 into multiple sections 171-173. Each lead 110 has a first 165 end and a second end 166. The first end 165 may be adapted to accommodate the light source die 140 or a wire bond 142 or both of them.

As shown in FIG. 1B, a first section 171 of each lead 110 may be partially exposed outside the body 120. The first section 171 may be made highly reflective. A second section 172 of each lead 110, between the first and second bends 161-162, may be exposed outside the body 120. A third section 173 of each lead 110 may be bent inwardly at the second bend 162, such that the third section 173 may be positioned below the body 120. The third section 173 together with the second end 166 may be attached to an external substrate (not shown), such as a printed circuit board (referred to hereinafter as a PCB).

The body 120 may encapsulate a portion of the leads 110. For example, the first section 171 and the first bend 161 may be at least partially encapsulated by the body 120. The first section 171 may not be encapsulated entirely. At least a portion of the first section 171 may be exposed, so that the light source die 140 may be attached to the first end 165. The top portion 120a of the body 120 further defines a reflective element 150 which comprises a reflective wall 152 and a bottom reflective surface 154. The reflective element 150 defines a cup shape and may be configured to direct light emitted from the light source die 140 in a specific direction 129.

The reflective wall 152 and the bottom reflective surface 154 may be highly reflective. In some instances, the reflective wall 152 may be coated with a metallic material. The cup defined by the reflective element 150 may be filled with a transparent encapsulant 130. The trans-parent encapsulant 130 may be an epoxy material, a silicon material, or other similar transparent material that encapsulates the light source die 140. The transparent encapsulant 130 may be mixed with a wavelength transforming material, such as yellow phosphorus, red phosphorus or any other similar material. For example, to produce white light, the light source die 140 may be a green or a blue LED die and the wavelength transforming material may be a yellow phosphor material, which produces white light in combination with a blue or green LED.

The height of the light-emitting device 100 is represented by line 125. In some instances, for example for silicone potting purposes, a taller device may be desired. For the embodiment shown in FIG. 1A-1B, one way to obtain a taller device may be by increasing proportionally both the height 123 of the top portion 120a and the height 124 of the bottom portion 120b, while maintaining the ratio between the top portion 120a and the bottom portion 120b.

However, this approach may increase the depth of reflective element 150, which may be commonly referred to as the reflector cup's depth. This may be because the height 123 of the top portion 120a is also representing the depth of the reflective element 150. A deep reflector cup may not be desirable, because this may limit the viewing angle of the device 100. Viewing angle may be one of the key specifications of any light-emitting device 100. Typically, a larger viewing angle may be more desirable in most applications.

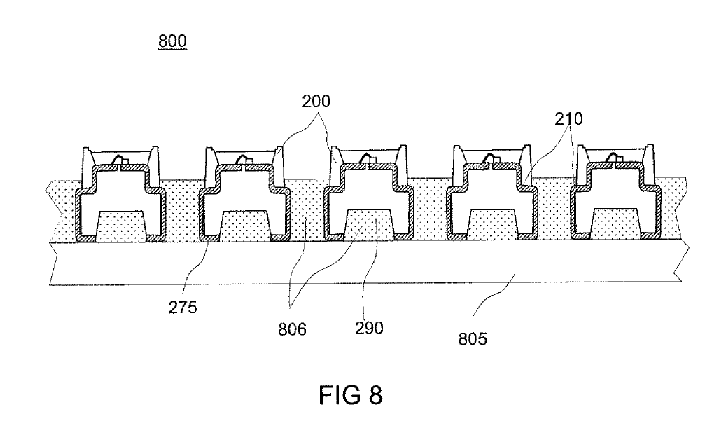

Alternatively, a taller device may be obtained by increasing the height 124 of the bottom portion 120b but maintaining the height 123 of the top portion 120a. This may not be desirable because increasing only the bottom portion 120b may affect the reliability performance. In addition, due to other requirements from the application aspect, such as for silicone potting processes, increasing the top portion 120a may be equally desirable to prevent spill over of the potting agent 806 (See FIG. 8) onto the transparent encapsulant 130.

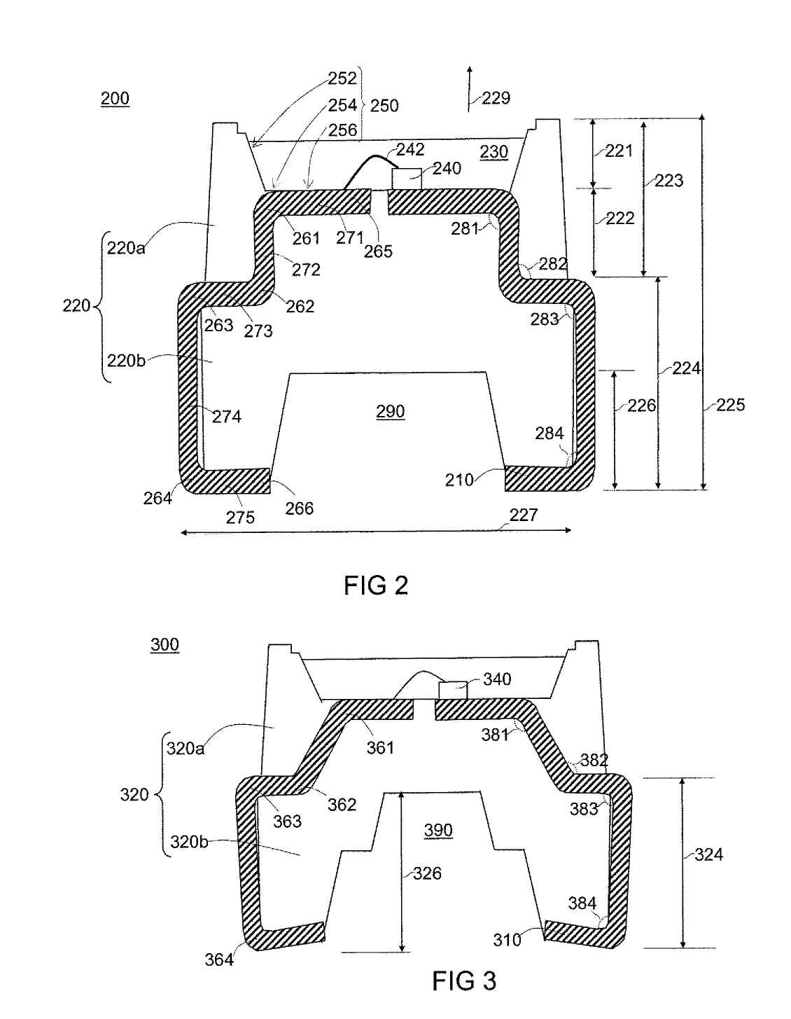

FIG. 2 illustrates an embodiment of a light-emitting device 200 with multiple bends shown in a cross-sectional view. Similar to the light-emitting device 100, the light-emitting device 200 comprises a plurality of leads 210, a body 220, and a light source die 240. The light source die 240 may be an LED die and may be encapsulated by a transparent encapsulant 230. The body 220 may be formed by using an opaque encapsulant material encapsulating a portion of the leads 210. Examples of the encapsulant material are poly parabanic acid resin (referred to hereinafter as PPA), liquid crystal polymer (referred to hereinafter as LCP), or any other similar plastic or ceramic material.

The body 220 further comprises a top portion 220a and a bottom portion 220b, which may be made from a top mold and a bottom mold, respectively. The top portion 220a further defines a reflective element 250 which comprises a reflective wall 252 and a bottom reflective surface 254. Top portions 256 of the leads 210 exposed on the bottom part of reflective surface 254 may also be part of the reflective element 250. The reflective element 250 is also known as reflector cup because the reflective element 250 usually defines a cup shape configured to direct light in a specific direction 229. A reflective material, such as any white, shinny, or metallic material may be coated on the reflective wall 252 or the bottom reflective surface 254 to increase reflectivity. However, certain materials that may be used to form the body 220, such as PPA and LCP may be sufficiently reflective that additional reflective coating may not be necessary.

The bottom portion 220b further defines a trench or a cavity 290, which may be used to accommodate potting agent 806 (See FIG. 8). The trench or the cavity 290 may have at least three advantages. First, the existence of the trench or the cavity 290 may require less material to be used to form the body 220, thus resulting in reduced material cost. Second, the trench or cavity 290 may accommodate potting agent 806 (See FIG. 8), which prevents moisture from seeping in through the bottom portion 220b. Also, the trench 290 may be configured to reduce the overall volume and weight of the light-emitting device 200, resulting in less stress within the light-emitting device 200.

Although the cross-sectional view shows only two leads 210, the light-emitting device 200 may have any number of leads 210. Each lead 210 comprises a plurality of bends 261-264, i.e. a first bend 261, a second bend 262, a third bend 263, and a fourth bend 264. The bends 261-264 may define angles 281-284 respectively, which may be between 45 and 135 degree. In the embodiment shown in FIG. 2, all the leads 210 are bent at 90 degree.

Each lead 210 may have a first end 265 and a second end 266. The first end 265 may be adapted to accommodate a wire bond 242 or a light source die 240, or both. The bends 261-264 further define each lead 210 into multiple sections 271-275. As shown in FIG. 2, each lead 210 may be defined into first 271, second 272, third 273, fourth 274, and fifth 275 sections. The fifth section 275 and alternatively, the second end 266 may be attached to an external substrate 805 (See FIG. 8), such as a PCB.

In the embodiment shown in FIG. 2, all the leads 210 may be bent at a 90 degree angle. Thus, the first 271, third 273, and fifth 275 sections may be substantially parallel. Similarly, the second 272 and fourth sections 274 may be substantially parallel. The second section 272, the third section 273 and the second bend 262 may be completely or substantially completely encapsulated by an encapsulant which forms the body 220. The first section 271 may be partially encapsulated by the encapsulant, such that the first end 265, exposed and configured to accommodate the wire bond 242 or the light source die 240.

The first bend 261 and the third bend 263 may be partially encapsulated inside the body 220. The fourth section 274, the fifth section 275 and the fourth bend 264 may be completely exposed externally for electrical connection to other external electronic components (not shown). Usually, the light-emitting device 200 may be soldered on to a PCB by means of the second end 266 or the entire fifth section 275.

Compared to the light-emitting device 100, the additional bends 261-264 provide additional flexibility to the designer to design a taller light source package without changing the ratio of the top portion 220a to the bottom portion 220b, and also without increasing the depth of reflective element 250 represented by line 221. This may be accomplished by increasing the height (represented by line 222) of the second section 272, accordingly.

For example, when the light-emitting device 200 is to be designed two times the package height 225, the height 223 of the top portion 220a and the height 224 of the bottom portion 220b can be increased proportionately. In order not to increase the reflective element's depth 221, the package designer may opt to only increase the height 222 of the second section 272 without changing the reflective element's depth 221.

It has been observed that having an unreasonably high or low ratio of the top portion 220a to the bottom portion 220b may yield lower reliability performance. Maintaining the ratio between 0.8 and 1.2 may produce optimized reliability performance. This may be due to the reason that there may be no covalent bonding between the encapsulant material that forms the body 220 and the leads 210. Having more bends 261-263 on the leads 210 encapsulated within the body 220 or partially within the body 220 may provide an improved mechanical interlocking means between the body 220 and the leads 210, thus improving the reliability performance.

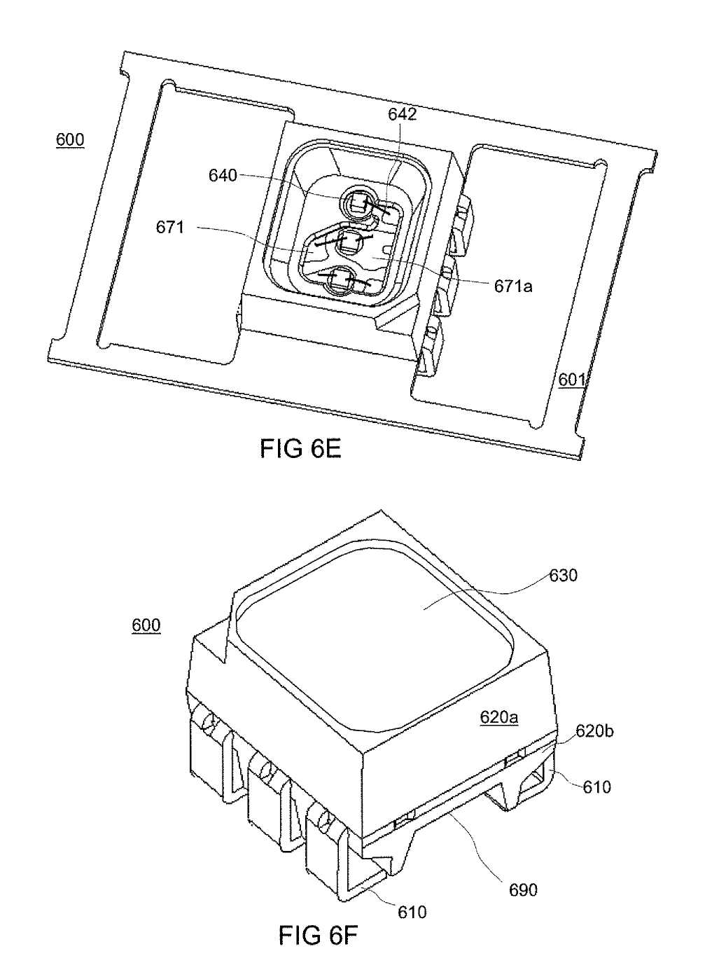

In addition to the bends 261-263, having apertures 615 in the leads 210 (See FIG. 6A-FIG. 6b), may provide additional mechanical interlocking means between the body 220 and the leads 210. While the apertures 615 may be optional, the existence of the apertures 615 (See FIG. 6A-6b) may reduce delamination between the leads 210 and the body 220. Each lead 210 may have at least one or more apertures 615 (See FIG. 6A-6b) located at the portion of the leads 210 which may be at least partially encapsulated by the body 220, for example along the sections 271-273 and the bends 261-263.

The depth 226 of the trench or the cavity 290 may be up to 80% of the height 224 of the bottom portion 220b. The existence of the trench or the cavity 290 may be beneficial in terms of reliability performance because it reduces the overall volume and weight of the body 220, thus reducing the internal stress within the light-emitting device 200.

In one embodiment of the light-emitting device 200, the height 225 of the light-emitting device 200 may be 3.5 mm, the height 223 of the top is portion 220a may be 1.6 mm. The height 224 of the bottom portion 220b may be 1.9 mm, while the depth 221 of the reflective element 250 may be 0.8 mm. The depth 226 of the trench or the cavity 290 may be 0.9 mm, while the width 227 of the light-emitting device 200 may be 4.5 mm. The height 222 of the second section 272 may be 0.8 mm, which may be more than two times the lead's 210 thickness of 0.2 mm.

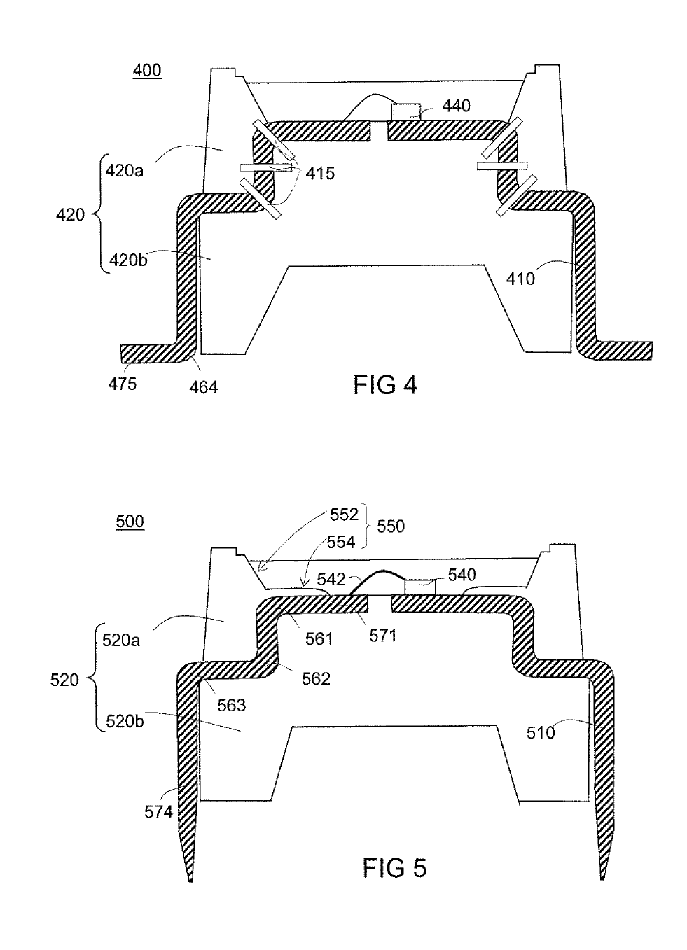

FIG. 3 illustrates an embodiment of another light-emitting device 300 with multiple bends 361-364. The light-emitting device 300 comprises a plurality of leads 310, a light source die 340 and a body 320 having a top portion 320a and a bottom portion 320b. The light-emitting device 300 may be similar to the light-emitting device 200 shown in FIG. 2 in all aspects except that the leads 310 may be bent at angles 381-384 not 90 degree and the trench or the cavity 390 may be a multi-step trench. The first and second angle 381-382 may be 135 degree. The third angle 383 may be 100 degree and the fourth angle 384 may be 80 degree. Due to the multi-step design, the depth 326 of the trench or the cavity 390 may be equal to the depth 324 of the bottom portion 320b.

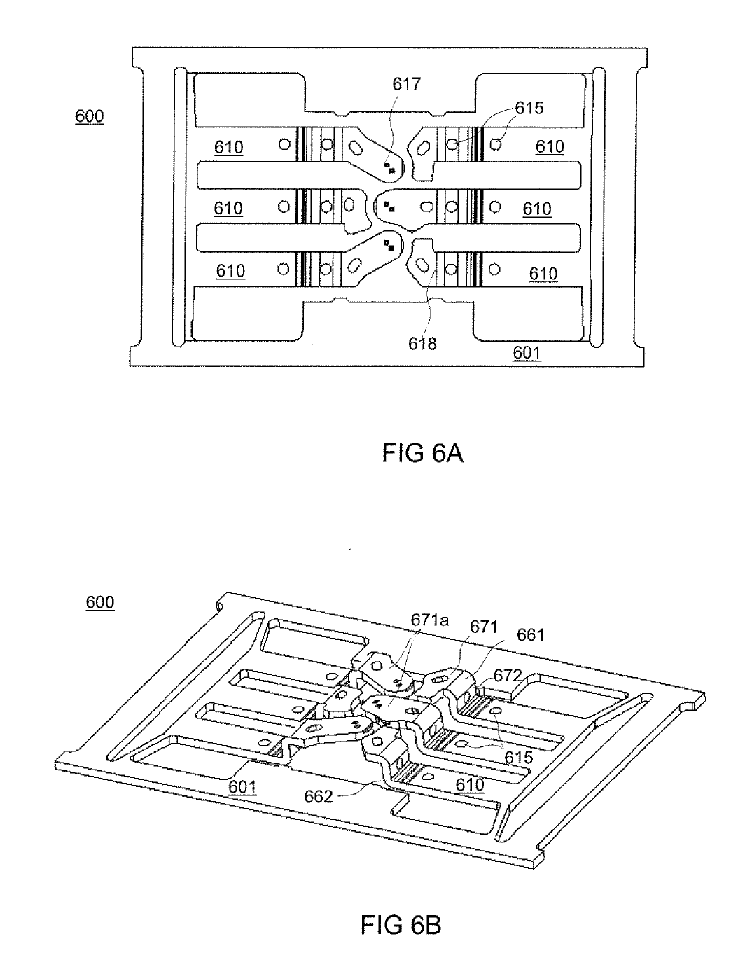

FIG. 4 illustrates an embodiment of another alternative design. FIG. 4 showing a light-emitting device 400 with outwardly bent leads 410. The light-emitting device 400 comprises a light source die 440, a plurality of leads 410 and a body 420 having a top portion 420a and a bottom portion 420b. The light-emitting device 400 may be similar to the light-emitting device 200 shown in FIG. 2 in all aspects, except that the leads 410 may be bent outwardly at the fourth bend 464 with each of the leads 410 further comprising a plurality of apertures 415.

Unlike the light-emitting device 200 in which the fifth section 275 may be located beneath the body 220 as shown in FIG. 2, the fifth section 475 of the light-emitting device 400 may be positioned on a PCB without being blocked by the body 420. This enables rework after the light-emitting device 400 being soldered on to the PCB. The outwardly bent leads 410 may require more space on the PCB compared to the light-emitting device 200 shown in FIG. 2. However, this may be a desirable tradeoff when later rework is contemplated.

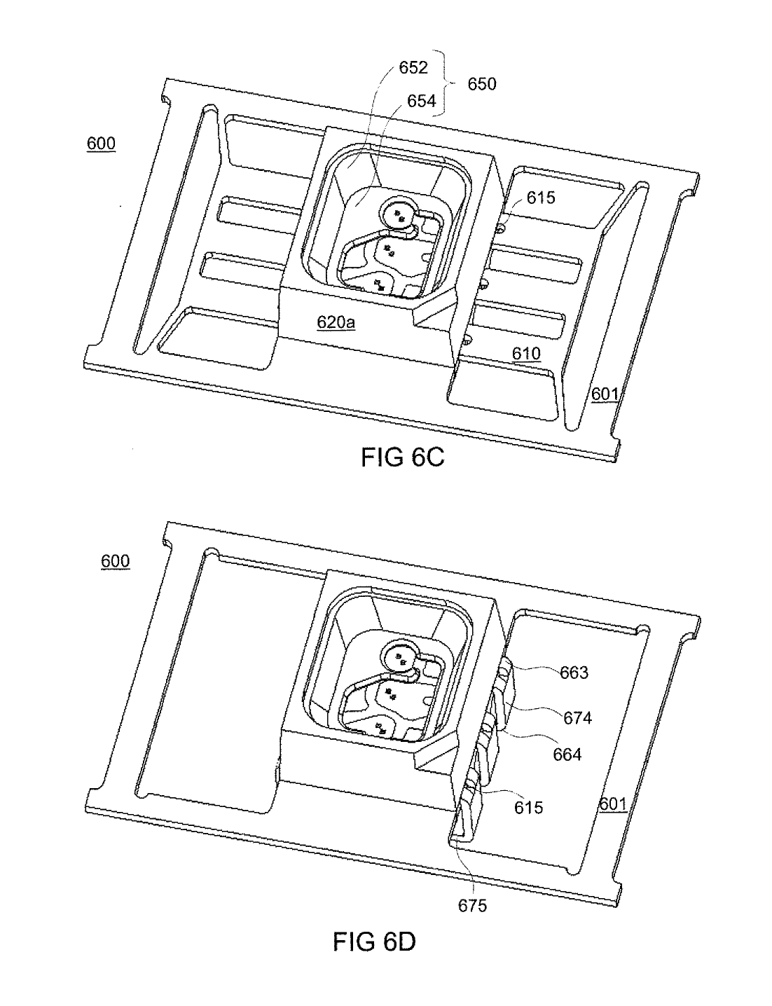

FIG. 5 illustrates an embodiment of a through-hole light-emitting device 500. The light-emitting device 500 comprises a plurality of leads 510, a light source die 540 and a body 520 having a top portion 520a and a lower portion 520b. The light-emitting device 500 may be similar to the light-emitting device 200 shown in FIG. 2, except with respect to the following two points.

First, each of the leads 510 in the light-emitting device 500 has three bends 561-563 instead of four bends 261-264, as in the light-emitting device 200 shown in FIG. 2. The fourth section 574 in each of the leads 510 may be extended beyond the body 520, and may be inserted to via holes (not shown) in a PCB configured to receive the light-emitting device 500.

Second, unlike the light-emitting device 200, the first section 571 of all the leads 510 may be substantially embedded inside the encapsulant forming the body 520, such that only a small portion of the leads 510 may be left exposed and adapted to accommodate the light source die 540 or wire bond 542. The reflective element 550 comprises the reflective wall 552 and the bottom reflective surface 554.

FIGS. 6A-6F illustrate how a 6-lead light-emitting device 600 with multiple bends 661-664 may be fabricated. First, a lead frame 601 for a single optical device, as shown in FIG. 6A, may be formed in a lead frame plate (not shown), simplifying the creation of lead frames 601 for multiple optical devices 600. The use of a lead frame 601 may hold the individual leads 610 in place, while the body 620 may be formed around the leads 610 by a molding process.

The shape and length of each lead 610 may be configured as desired to accommodate design requirements. The leads 610 may be formed in the lead frame 601 by stamping, laser, etching, cutting or otherwise forming openings in the lead frame 601 leaving the leads 610 defined by the openings. Dimples or roughened areas 617 may be stamped or formed in the leads 610 to facilitate attachment of the light source dies 640. Apertures 615 may be stamped, cut, laser, etched, or otherwise formed in the leads 610. Folding lines 618 may also be stamped or formed indicating the location for the bends 661-664.

Next, all of the leads 610 may be bent twice as shown in FIG. 6B, forming the first and second bends 661-662, as well as the first and second sections 671-672, respectively. Some of the leads 610 may have larger first sections 671a configured to accommodate the light source dies 640. After fanning the first and second bends 661-662, the body 610 may be then fabricated using a top mold and a bottom mold (not shown). FIG. 6C shows a top portion 620a of the body 620. The bottom portion 620b may be partially hidden beneath the top portion 620a in FIG. 6C. FIG. 6F shows the bottom portion 620b and the trench or cavity 690 defined by the bottom portion 620b. As shown in FIG. 6C, the top portion 620a further defines a reflective element 650 which comprises a reflective wall 652 and a bottom reflective surface 654. The lead frame 601 holds the entire structure in place during the molding process.

After the molding process, all the leads 610 may be separated from the lead frame 601 and may go through additional bending processes, in which the third and fourth bends 663-664, and the third, fourth an fifth sections 673-675 of the leads 610 may be formed. As shown in FIG. 6D, the fifth sections 675 of the leads 610 may be bent inwardly beneath the body 620. The third bends 663 of each lead 610 define the apertures 615, which may be partially encapsulated by the body 610.

The next steps may be die attach and wire bond processes. As shown in FIG. 6E, three light source dies 640 may be attached to the larger first sections 671a and the required wire bonds 642 may be bonded to the other first sections 671, correspondingly. The 6-lead light-emitting device 600 may have uni-color light source dies 640, or alternatively, each of the light source dies 640 may be adapted to emit different colors. For use in electronic infotainment display systems, each light-emitting device 600 may have three light source dies 640, with each die 640 operable to illuminate one of red, green and blue light, respectively.

Similarly, during the die attach and wire bond processes, the lead frame 601 may hold the entire structure in place. Next the light-emitting device 600 may go through an encapsulation process in which the reflective element 650 may be filled by a transparent encapsulant 630. The transparent encapsulant 630 can be any epoxy material or any silicon material. Finally, the lead frame 601 may then be completely separated and discarded, yielding a complete light-emitting device 600, as shown in FIG. 6F.

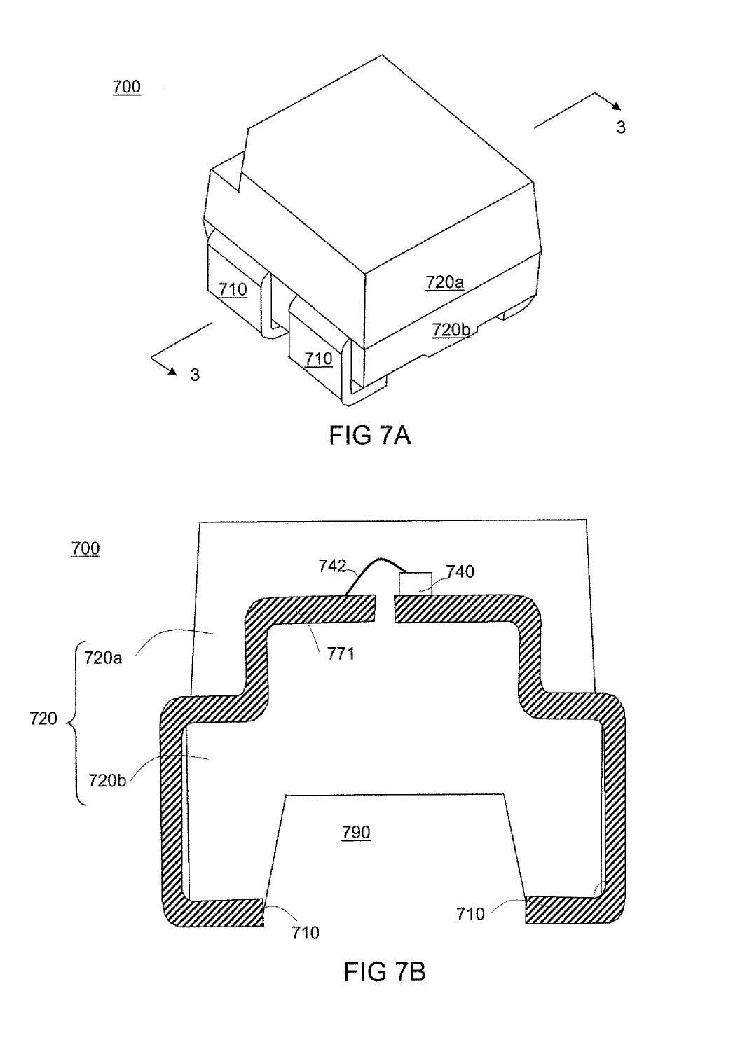

FIG. 7A illustrates a non-optical device 700 with multiple bends. FIG. 7B illustrates a cross-sectional view of the non-optical device 700 along line 3-3 of FIG. 7A. The non-optical device comprises a plurality of leads 710, a die 740, and a body 720, which further comprises a top portion 720a, which may be formed using a top mold, and a bottom portion 720b, which may be formed using a bottom mold. The bottom portion 720b farther defines a cavity or a trench 790. The cross-sectional view, shown in FIG. 7B may be similar to the cross-sectional view shown in FIG. 2, except that the non-optical device 700 may not have any reflective element 250 or transparent encapsulant 230, shown in FIG. 2. In addition, the die 740, the first section of the leads 771, the wire bond 742 may be encapsulated entirely by the opaque body 720a.

FIG. 8 illustrates a cross section view of an electronic infotainment display system 800. Electronic infotainment display systems 800 may be commonly found in stadiums, discotheques, electronic traffic sign displays and infotainment boards on streets. Each electronic infotainment display system 800 may generally have an array of light-emitting devices such as the light-emitting devices 100, 200, 300, 400, 500, 600, as shown in FIGS. 1-6. For example, in the electronic infotainment display system 800, each of the light-emitting devices 200 may represent a pixel. For a color display system, the light-emitting devices 200 may have at least three light source dies 240, each capable of emitting red, green or blue light, respectively. Alternatively, three neighboring light-emitting devices 200, each capable of emitting a single color may, collectively represent a pixel.

As shown in FIG. 8, the light-emitting devices 200 may be attached to a substrate 805, usually a PCB. The fifth sections 275 of the leads 210 may be soldered or otherwise attached, as known in the art to the PCB. As the electronic infotainment display system 800 may be used in outdoor conditions exposed to extreme weather conditions, such as rain, snow, hail, heat, cold, wind, and direct sun light, the substrate 805 and all the electronics components including the light-emitting devices 200 may require protection from the elements of nature. This may be accomplished utilizing a silicone potting process.

The silicone potting process utilizes a potting agent 806 to encapsulate electronic devices, including the light-emitting devices 200 and the substrate 805. The potting agent 806 may include pourable insulating resins, such as epoxies, silicones, urethanes, hybrids, or any other similar material. The potting agent 806 may be cast into cavities containing electronic components to insulate, protect, and hold them in place.

The potting agent 806 may thus protect the electronic components from moisture, as well as mechanical stresses, such as shock and vibration. As shown in FIG. 8, the cavity or trench 290 may be configured to accommodate the potting agent 806.

For larger electronic infotainment display systems 800, other non-optical components such as drivers and controller packaged integrated circuits may be attached on the substrate 805. For such non-optical components, similar packaging to that shown in FIG. 7 may be utilized.

Although specific embodiments of the invention have been described and illustrated herein above, the invention should not be limited to the specific forms or arrangements of parts so described and illustrated. For example, light source die described above may be LEDs die or some other future light source die. Likewise, although a light-emitting device with three die and six leads was discussed, the light-emitting device may contain any number of die or leads, as known or later developed without departing from the spirit of the invention, The scope of the invention is to be defined by the claims appended hereto and their equivalents.

What is claimed is:

1. A light-emitting device, comprising:
a plurality of leads;
a light source die attached to one of the plurality of leads; and,
a body, the body being formed of an opaque encapsulant;
wherein each of the plurality of leads further comprises at least first, second, and third bends defining each of the plurality of leads into at least first, second, third and fourth sections, and wherein the second section between the first and second bends, the third section between the second and third bends, and the second bend of each lead are substantially encapsulated by the opaque encapsulant.

2. The light-emitting device of claim 1, wherein each of the leads further comprises a fourth bend defining a fifth section.

3. The light-emitting device of claim 1, wherein each of the leads further comprises a first end and a second end, the first end of each lead is configured to accommodate the light source die, a wire bond or both, whereas the second end is configured to be attachable to an external substrate.

4. The light-emitting device of claim 1, wherein a top portion of the body defines a reflective element configured to reflect light generated from the light source die in a predetermined direction.

5. The light-emitting device of claim 1, wherein a portion of the body defines a trench or a cavity in a bottom portion of the body.

6. The light-emitting device of claim 1, wherein the light source die is encapsulated by a transparent encapsulant.

7. The light-emitting device of claim 1, wherein the body further comprises a top portion formed using a top mold and a bottom portion formed using a bottom mold, the top portion and the bottom portion have a height ratio between 0.8 and 1.2.

8. The light-emitting device of claim 1, wherein one or more of the plurality of leads further comprises an aperture configured to provide mechanical interlock between the body and the one or more of the plurality of leads.

9. The light-emitting device of claim 8, wherein the aperture is located in at least one of the first, second or third bends of the one or more of the plurality of leads.

10. The light-emitting device of claim 1, wherein each of the first, second, and third bends defines a degree between 45 to 135 degrees.

11. The light-emitting device of claim 1, wherein the light-emitting device forms a part of an electronic infotainment display system.

12. A packaged device, comprising:
a plurality of leads;
a die attached on one of the plurality of leads;
a body, the body being formed by an encapsulant; and,
first, second and third bends in each of the plurality of leads, the first second and third bends further defines each of the plurality of leads into first, second, third and fourth sections;
wherein at least the second section of each of the plurality of the leads, between the first and second bends, the third section between the second and third bends, and the second bends are substantially encapsulated by the encapsulant.

13. The packaging of claim 12, wherein each of the plurality of leads further comprises a fourth bend.

14. The packaging of claim 12, the first end of each of the plurality of leads is configured to accommodate the light source die, a wire bond or both, whereas the second end is configured to be attachable to an external substrate.

15. The packaging of claim 12, wherein a bottom portion of the body defines a trench or a cavity.

16. The packaging of claim 12, wherein the body further comprises a top portion formed using a top mold and a bottom portion formed using a bottom mold, the top portion and the bottom portion have a height ratio between 0.8 and 1.2.

17. The packaging of claim 1, wherein each of the plurality of leads further comprises at least one aperture configured to provide mechanical interlock between the body and each of the plurality of leads.

18. The packaging of claim 17, wherein the at least one aperture is located in at least one of the first, second or third bends.

19. The packaging of claim 1, wherein each of the first, second, and third bends defines a degree between 45 to 135 degrees.

20. An electronic infotainment display system, comprising:
a substrate;
a plurality of packaged light sources attached to the substrate, each packaged light source further comprises:
a plurality of leads, each of the plurality of leads having first, second, third and fourth bends;
a light source die; and,
a body, the body being formed of an opaque encapsulant encapsulating at least the first and second bends of each of the plurality of leads; and,
a potting agent, wherein the potting agent encapsulates the substrate, and portions of each of the plurality of leads exposed outside the body of each packaged light source.
